(19) United States
(12) Patent Application Publication
(10) Pub. No.: US 2015/0371717 A1
(43) Pub. Date: Dec. 24, 2015

(54) SEMICONDUCTOR MEMORY DEVICE

(71) Applicant: SK hynix Inc., Gyeonggi-do (KR)

(72) Inventor: Sang-Il PARK, Gyeonggi-do (KR)

(21) Appl. No.: 14/552,103

(22) Filed: Nov. 24, 2014

(30) Foreign Application Priority Data
Jun. 18, 2014 (KR) 10-2014-0074165

(51) Int. Cl. G11C 29/12

(52) U.S. Cl. CPC G11C 29/12; G11C 2029/1204

(57) ABSTRACT

A semiconductor memory device includes a voltage supply part suitable for providing a predetermined test detection voltages to a pair of bit lines respectively, during a test operation for detecting a failure between a word line and the pair of bit lines; a column connection section suitable for electrically coupling the pair of bit lines and a pair of segment lines to each other, respectively, in response to a column selection signal; and a precharge section suitable for precharging the pair of segment lines to a precharge voltage corresponding to one of the test detection voltages during a failure detection time section while performing the test operation.

### CROSS-REFERENCE TO RELATED APPLICATIONS

The present application claims priority of Korean Patent Application No. 10-2014-0074165, filed on Jun. 18, 2014, which is incorporated herein by reference in its entirety.

### BACKGROUND

1. Field

Various exemplary embodiments of the present invention relate to a semiconductor design technology, and more particularly, to a semiconductor memory device capable of detecting a failure between a word line and a bit line.

2. Description of the Related Art

Semiconductor memory devices, such as Double Data Rate Synchronous Dynamic Random Access Memory (DDR SDRAM), include more than ten million memory cells and store data or output data according to a command from a chipset, such as a central processing unit. The operation of storing data is referred to as a write operation, and the operation of outputting stored data is referred to as a read operation. Semiconductor memory devices transfer data, which is inputted through a data pad, through data input paths and store the data into memory cells during a write operation. Semiconductor memory devices transfer data, which is stored in memory cells, through data output paths, and output the data to the data pads during read operations.

FIG. 1 is a circuit diagram illustrating an existing semiconductor memory device. For reference, a semiconductor memory device comprises more than ten million memory cells, and FIG. 1 shows a single memory cell for convenience of description.

An operation of the existing semiconductor memory device will be described with reference to FIG. 1.

During an active operation, when a word line WL corresponding to a memory cell 110 is activated, a cell transistor T1 of the memory cell 110 is turned on, and a cell capacitor C1 of the memory cell 110 and a positive bit line BL are electrically coupled to each other. Data stored in the cell capacitor C1 is transferred to the positive bit line BL through charge sharing. For reference, before the charge sharing between the cell transistor T1 and the positive bit line BL, an equalization section 120 equalizes the positive bit line BL and a negative bit line /BL to a bit line precharge voltage VBLP. Therefore, before the activation of the word line WL, the positive and negative bit lines BL and /BL are equalized to the bit line precharge voltage VBLP. Also, after the activation of the word line WL, the positive and negative bit lines BL and /BL have a minute voltage difference due to the charge sharing between the cell transistor T1 and the positive bit line BL.

A bit line sense amplification section 130 detects and amplifies the minute voltage difference between the positive and negative bit lines BL and /BL. When the voltage of the positive bit line BL is higher than the voltage of the negative bit line /BL, the voltage of the positive bit line BL is amplified to a pull-up power voltage RTO, and the voltage of the negative bit line /BL is amplified to a pull-down power voltage SB. On the other hand, when the voltage of the positive bit line BL is lower than the voltage of the negative bit line /BL, the voltage of the positive bit line BL is amplified to the pull-down power voltage SB, and the voltage of the negative bit line /BL is amplified to the pull-up power voltage RTO.

During a read operation, a semiconductor memory device activates a column selection signal YI by decoding a column address, which is inputted for the read operation. A transistor of a first switching section 140 is turned on in response to the column selection signal YI, and the positive and negative bit lines BL and /BL and positive and negative segment input/output lines SIO and /SIO are electrically coupled to each other, respectively. That is, the amplified data on the positive bit fine BL is transferred to the positive segment input/output line SIO, and the amplified data on the negative bit line /BL is transferred to the negative segment input/output bit line /SIO.

When a transistor of an input/output switching section 150 is turned on in response to an input/output control signal IO corresponding to the column address, the positive and negative segment input/output lines SIO and /SIO are electrically coupled to positive and negative local input/output lines LIO and /LIO, respectively. That is, the data, which is transferred to the positive segment input/output line SIO, is transferred to the positive local input/output line LIO, and the data, which transferred to the negative segment input/output bit line /SIO, is transferred to the negative local input/output bit line /LIO. A read driving section 160 drives a global input/output line GIO according to data transferred through the positive and negative local input/output lines LIO and /LIO.

To sum up, data stored in the memory cell 110 is transferred to the positive and negative segment input/output lines SIO and /SIO through the positive and negative bit lines BL and /BL in response to the column selection signal YI. Data transferred to the positive and negative segment input/output lines SIO and /SIO is transferred to the positive and negative local input/output lines LIO and /LIO in response to an input/output control signal IO. Data transferred to the positive and negative local input/output lines LIO and /LIO is transferred to the global input/output line GIO by the read driving section 160. Data transferred as such is eventually outputted to an external through the input/output pad (not illustrated).

During the write operation, data inputted from an external is transferred in reverse direction to the direction of data transfer during the read operation. That is, data inputted from the external is transferred to the positive and negative bit lines BL and /BL sequentially through the global input/output line GIO, the positive and negative local input/output lines LIO and /LIO, and the positive and negative segment input/output lines SIO and /SIO by a write driving section 170. Data transferred as such is eventually stored to the memory cell 110.

The semiconductor memory device performs various test operations before going out to the market as a commercial product. Through the test operations, reliability of the semiconductor memory device is guaranteed. An Unlimited Sensing Delay (USD) test operation is one of the various test operations.

Through the USD test, a leakage current path between the word line and the bit line is detected. Normally, the word line and the bit line are open or electrically decoupled. However, when the word line and the bit line are shorted, for whatever reason, a leakage current path between the word line and the bit line may form, and leakage current may flow through the leakage current path. The leakage current indicates a loss of charge through the bit line, which may result in the loss of data stored in the memory cell. Therefore, the USD test, capable of detecting the unexpected leakage current path, is required to guarantee normal operation and the reliability of the semiconductor memory device is elevated through the USD test.

Generally, during the USD test, test data having a logic LOW level is stored in the memory cell, the word line is activated for a predetermined time, and then the test data is detected through the amplification operation and the read operation. When there a leakage current path is formed between the word line and the bit line, the test data of logic LOW will be lost, and the data of logic HIGH will be detected. When there is not a leakage current path between the word line and the bit line, the original test data of logic LOW will be detected. A tester will cure the failure of the semiconductor memory device or discard the semiconductor memory device having the leakage current path between the word line and the bit line according to the USD test result.

Meanwhile, the size of the semiconductor memory device becomes smaller, and the space margin between the circuits in the semiconductor memory device is shrinking as the circuit design and process technology of the semiconductor memory device are developed. According to the development trend, the space margin between the word lines and the bit lines is also shrinking, which means a higher likelihood of a short between the word line and the bit line. Therefore, the significance of a USD test capable of detecting failures between word lines and bit lines is getting more attention.

### SUMMARY

Various embodiments of the present invention are directed to a semiconductor memory device capable of providing an optimal environment for an unlimited sensing delay (USD) test operation by controlling peripheral circuits to a test target circuit during the USD test operation.

In accordance with an embodiment of the present invention, a semiconductor memory device includes a voltage supply part suitable for providing predetermined test detection voltages to a pair of bit lines, respectively, during a test operation for detecting a failure between a word line and the pair of bit lines; a column connection section suitable for electrically coupling the pair of bit lines and a pair of segment lines to each other, respectively, in response to a column selection signal; and a precharge section suitable for precharging the pair of segment lines to a precharge voltage corresponding to one of the test detection voltages during a failure detection time section while performing the test operation.

The semiconductor memory device may further include a sense amplification section suitable for detecting and amplifying a voltage difference between the pair of bit lines after the failure detection time section during the test operation.

The precharge section may comprise a precharge driving unit suitable for driving the pair of segment lines to the precharge voltage; and a precharge control unit suitable for controlling the precharge driving unit during the test operation.

The semiconductor memory device may further include a precharge voltage selection section suitable for selecting a test voltage corresponding to a test data stored during the test operation in a memory cell of the semiconductor memory device as the precharge voltage.

The precharge voltage selection section may comprise a voltage generation unit suitable for generating a plurality of test voltages respectively corresponding to a plurality of possible test data; and a selection output unit suitable for selecting one among the plurality of test voltages corresponding to the test data stored during the test operation in the memory cell as the precharge voltage.

The test detection voltages include voltages provided to the pair of bit lines through an equalization operation and a charge sharing between a memory cell of the semiconductor memory device and one of the pair of bit lines.

The voltage supply part may comprise an equalization section suitable for equalizing the pair of bit lines to an equalization voltage; and a memory cell electrically coupled to the wore line and one of the pair of bit lines.

The precharge voltage may correspond to the equalization voltage.

The precharge section may comprise a precharge driving unit suitable for driving the pair of segment lines to the equalization voltage; and a precharge control unit suitable for controlling the precharge driving unit during the test operation.

The semiconductor memory device may further include an input/output connection section suitable for electrically coupling the pair of segment lines and a pair of local input/output lines to each other, respectively, in response to an input/output selection signal.

The input/output connection section may be activated after the failure detection time section.

In accordance with an embodiment of the present invention, a semiconductor memory device includes a pair of bit lines including first and second bit lines; a voltage supply part suitable for providing predetermined test detection voltages to each of the first and second bit lines, respectively, during a test operation for detecting a failure between a word line and the pair of bit lines; a column connection section suitable for electrically coupling the first and second bit lines and first and second segment lines to each other, respectively, in response to a column selection signal; and a precharge section suitable for precharging the first and second segment lines to first and second precharge voltages corresponding to the test detection voltages during a failure detection time section while performing the test operation.

The precharge section may comprise a first precharge unit suitable for precharging the first segment line to a first precharge voltage; and a second precharge unit suitable for precharging the second segment bit line to a second precharge voltage.

The voltage supply part may comprise an equalization section suitable for equalizing the pair of bit lines to an equalization voltage; and a memory cell electrically coupled to the word line and the first bit line.

Each of the first precharge voltage and the test detection voltage may provide to the first bit line corresponds to the equalization voltage and a charge-shared voltage between the memory cell and the first bit line.

The first precharge unit may comprise a precharge driving unit suitable for driving the first segment line to the first precharge voltage; and a precharge control unit suitable for controlling the precharge driving unit during the test operation.

The semiconductor memory device may further include a precharge voltage selection section suitable for selecting a test voltage corresponding to a test data stored during the test operation in the memory cell as the first precharge voltage.

Each of the second precharge voltage and the test detection voltage may provide to the second bit line corresponds to the equalization voltage.

The semiconductor memory device may further include an input/output connection section suitable for electrically coupling the pair of segment lines and a pair of local input/output lines to each other, respectively, in response to an input/output selection signal.

The input/output connection section may be activated after the failure detection time section.

In accordance with an embodiment of the present invention, a semiconductor memory device may provide optimal environment for the unlimited sensing delay (USD) test operation by controlling peripheral circuits to a test target circuit during the USD test operation.

### BRIEF DESCRIPTION OF THE DRAWINGS

FIG. 1 is a circuit diagram illustrating an existing semiconductor memory device.

FIG. 2 is a circuit diagram illustrating a semiconductor memory device in accordance with an embodiment of the present invention.

FIG. 3 is a waveform diagram illustrating a USD test operation of a semiconductor memory device shown in FIG. 2.

FIG. 4 is a circuit diagram illustrating a semiconductor memory device in accordance with an embodiment of the present invention.

FIG. 5 is a circuit diagram illustrating a precharge voltage selection section shown in FIG. 4.

FIG. 6 is a waveform diagram illustrating a USD test operation of a semiconductor memory device shown in FIG. 4.

FIG. 7 is a circuit diagram illustrating a semiconductor memory device in accordance with an embodiment of the present invention.

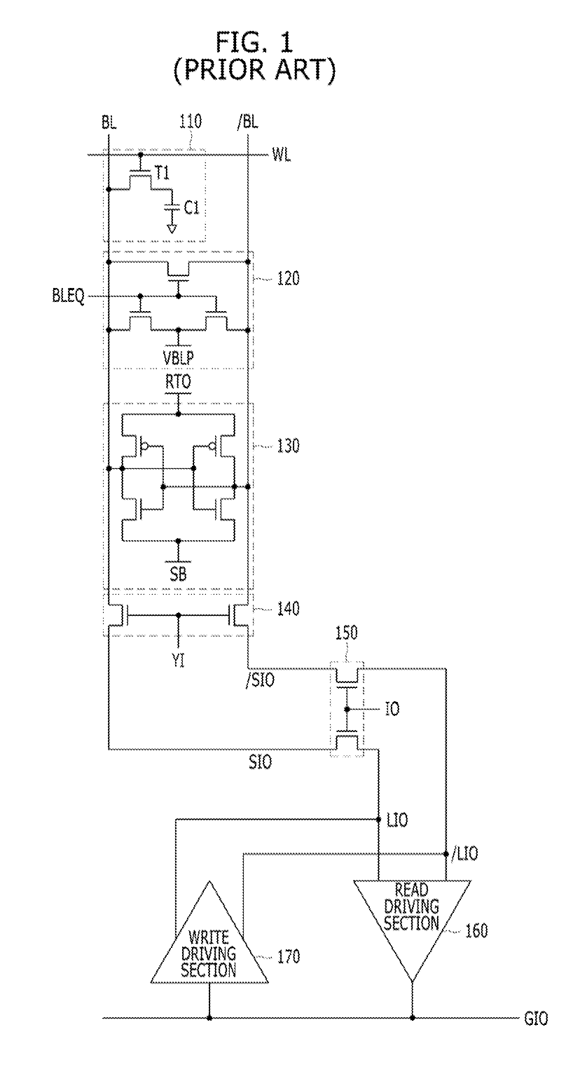

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. The drawings are not necessarily to scale and, in some instances, proportions may have been exaggerated in order to clearly illustrate features of the embodiments. Throughout the disclosure, reference numerals correspond directly to the like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. When a first layer is referred to as being “on” a second layer or “on” a substrate, it not only refers to where the first layer is formed directly on the second layer or the substrate but also where a third layer exists between the first layer and the second layer or the substrate.

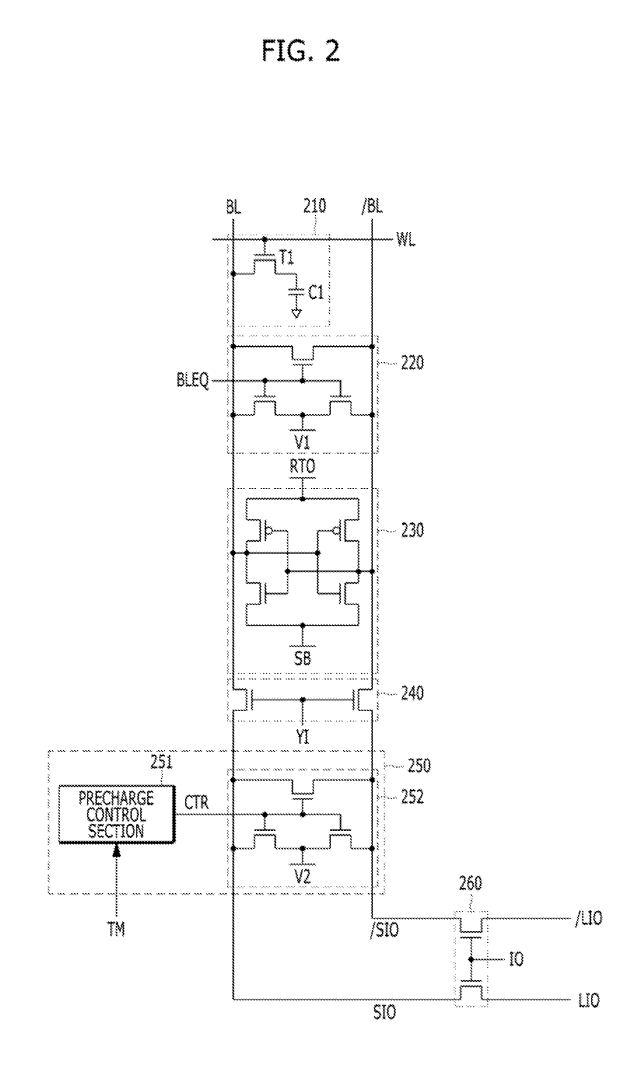

FIG. 2 is a circuit diagram illustrating a semiconductor memory device in accordance with an embodiment of the present invention.

Referring to FIG. 2, the semiconductor memory device may include a memory cell 210, an equalization section 220, a bit line sense amplification section 230, a column connection section 240, a precharge section 250, and an input/output connection section 260.

The memory cell 210 may store data, and may include a cell transistor T1 and a cell capacitor C1. The cell transistor T1 may be electrically coupled to a word line WL at its gate, and may electrically couple the cell capacitor C1 and a positive bit line BL to each other when the word line WL is activated. For reference, although FIG. 2 shows the memory cell 210 electrically coupled to the positive bit line BL between the positive and negative bit lines BL and /BL, the memory cell 210 may be coupled to the negative bit line /BL, depending on the design.

The equalization section 220 may equalize the positive and negative bit lines BL and /BL to an equalization voltage V1 in response to an equalization control signal BLEQ. The equalization voltage V1 may be a half of data voltage. The bit line sense amplification section 230 may detect and amplify a voltage difference between the positive and negative bit lines BL and /BL through an active operation a predetermined time after the activation of the word line WL. The predetermined time may be set as desired by a USD test operator, and may correspond to a failure detection time section, which will be described later.

The column connection section 240 may electrically couple the positive and negative bit lines BL and /BL and positive and negative segment input/output lines SIO and /SIO to each other, respectively, in response to a column selection signal YI. The column connection section 240 may include a first MOS transistor for electrically coupling the positive bit line BL and the positive segment input/output line SIO to each other in response to the column selection signal YI, and a second MOS transistor for electrically coupling the negative bit line /BL and the negative segment input/output bit line /SIO to each other in response to the column selection signal YI.

The precharge section 250 may precharge the positive and negative segment input/output lines SIO and /SIO to a precharge voltage V2 during the failure detection time section while performing the test operation. The precharge section 250 may include a precharge control unit 251, and a precharge driving unit 252. The failure detection time section will be described later.

The precharge control unit 251 may generate a precharge control signal CTR in response to a test signal TM, which is enabled during the test operation. The precharge control signal CTR is enabled during the failure detection time section. The precharge driving unit 252 may drive the positive and negative segment input/output lines SIO and /SIO to the precharge voltage V2 in response to the precharge control signal CTR. The precharge voltage V2 may correspond to the equalization voltage V1 and, for example, may be the same as the equalization voltage V1.

The input/output connection section 260 may electrically couple the positive and negative segment input/output lines SIO and /SIO and the positive and negative local input/output lines LIO and /LIO to each other, respectively, in response to an input/output selection signal IO. The input/output connection section 260 may include a third MOS transistor for electrically coupling the positive segment input/output line SIO and the positive local input/output line LIO to each other in response to the input/output selection signal 10, and a fourth MOS transistor for electrically coupling the negative segment input/output bit line /SIO and the negative local input/output bit line /LIO to each other in response to the input/output selection signal IO.

Hereinafter, for convenience of description, a test detection voltage will be defined as follows.

When the word line WL is activated, a value of data stored in the memory cell 210 as well as the equalization voltage V1 may be reflected to the positive bit line BL. That is, the value of stored data as well as the equalization voltage V1 may be provided to the positive bit line BL. During the USD test, a test result may be obtained by detecting the voltage of the positive bit line BL. Therefore, the equalization voltage V1 and the value of stored data, which are provided to the positive bit line BL, may be defined as the test detection voltage for the USD test operation. In this case a voltage supply part for supplying the test detection voltage to the positive bit line BL may comprise the memory cell 210 for providing the value of stored data, and the equalization section 220 for providing the equalization voltage V1.

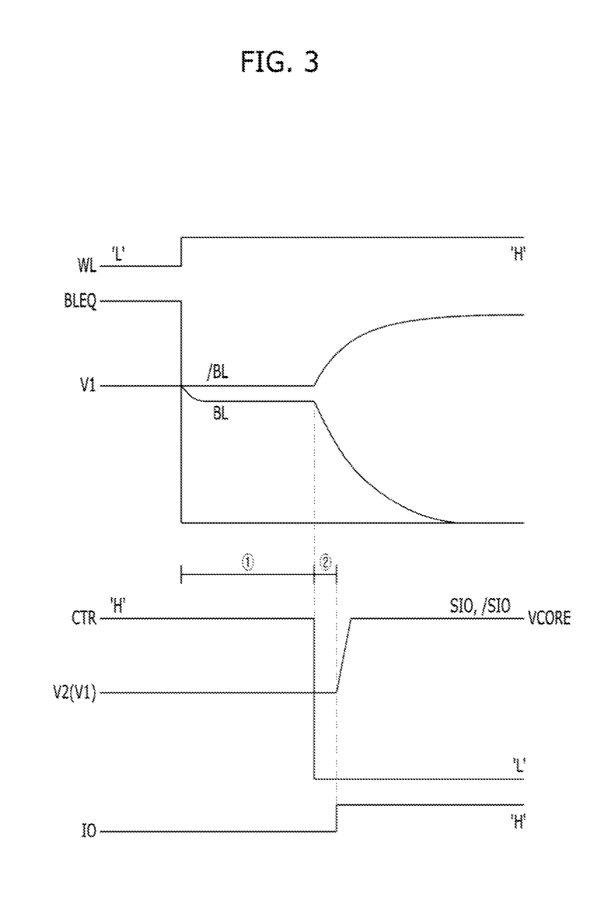

FIG. 3 is a waveform diagram illustrating the USD test operation of the semiconductor memory device shown in FIG. 2. For convenience of description, it is assumed that data of logic ‘LOW’ L is stored in the memory cell stores during the USD test operation.

The positive and negative bit lines BL and /BL may be precharged to the equalization voltage V1 before the word line WL is activated. When the word line WL is activated to a logic ‘HIGH’ H, and the equalization control signal BLEQ is disabled, the positive and negative bit lines BL and /BL may have a minute voltage difference due to the charge sharing between the cell transistor T1 and the positive bit line BL. Hereinafter, a time section “1” before the positive and negative bit lines BL and /BL are amplified after activation of the word line WL during the USD test operation is referred to as the failure detection time section. As the failure detection time section “1” becomes longer, a failure detection rate of the USD test becomes greater.

The precharge control signal CTR may be enabled during the failure detection time section “1”. That is, during the failure detection time section “1”, the positive and negative segment input/output lines SIO and /SIO may have the precharge voltage V2, which is the same as the equalization voltage V1. The precharge voltage V2 of the positive and negative segment input/output lines SIO and /SIO indicate that a voltage difference of the column connection section 240, or the voltage difference between each of the positive and negative bit lines BL and /BL and the positive and negative segment input/output lines SIO and /SIO may be minimized during the failure detection time section “1” and therefore, means that leakage current flowing through the column connection section 240 may be minimized during the failure detection time section “1”.

As described above, the USD test detects failure of the word line WL and the positive and negative bit lines BL and /BL. Therefore, unexpected leakage current flowing through the column connection section 240 may exert a negative influence on the USD test result. Accordingly, leakage current flowing through the column connection section 240 may be reduced by minimizing the voltage difference between the positive and negative bit lines BL and /BL and the positive and negative segment input/output lines SIO and /SIO. Therefore, a USD test result on only the word lines WL and the positive and negative bit lines BL and /BL, with minimized noise, may be obtained.

In accordance with an exemplary embodiment of the present invention, a semiconductor memory device may provide an optimized environment for performing stable USD test operations by minimizing the voltage difference between the positive and negative bit lines BL and /BL and the positive and negative segment input/output lines SIO and /SIO during the failure detection time section “1”.

Meanwhile, the input/output selection signal IO may be enabled to a logic ‘HIGH’ H at time section “2” after the precharge control signal CTR is disabled to a logic ‘LOW’ L. Although, the input/output selection signal IO may be ideally enabled at the time of disablement of the precharge control signal CTR, there may be a margin of the time section “2” between the enablement of the input/output selection signal IO and the disablement of the precharge control signal CTR, for a stable operation. The positive and negative segment input/output lines SIO and /SIO may be precharged to a core voltage VCORE. When the input/output selection signal IO is enabled, the positive and negative segment input/output lines SIO and /SIO may be driven to the core voltage VCORE due to the core voltage VCORE of the positive and negative local input/output lines LIO and /LIO. That is, the positive and negative segment input/output lines SIO and /SIO may have a precharge voltage V2 corresponding to the equalization voltage V1 during the failure detection time section “1” and have the core voltage VCORE after that. The driving of the positive and negative segment input/output lines SIO and /SIO to the core voltage VCORE may be for faster and more stable output of amplified data on the positive and negative bit lines BL and /BL.

In accordance with an exemplary embodiment of the present invention, the semiconductor memory device may output the test result of the positive and negative bit lines BL and /BL in a faster and more stable way by enabling the input/output selection signal IO after the failure detection time section “1”.

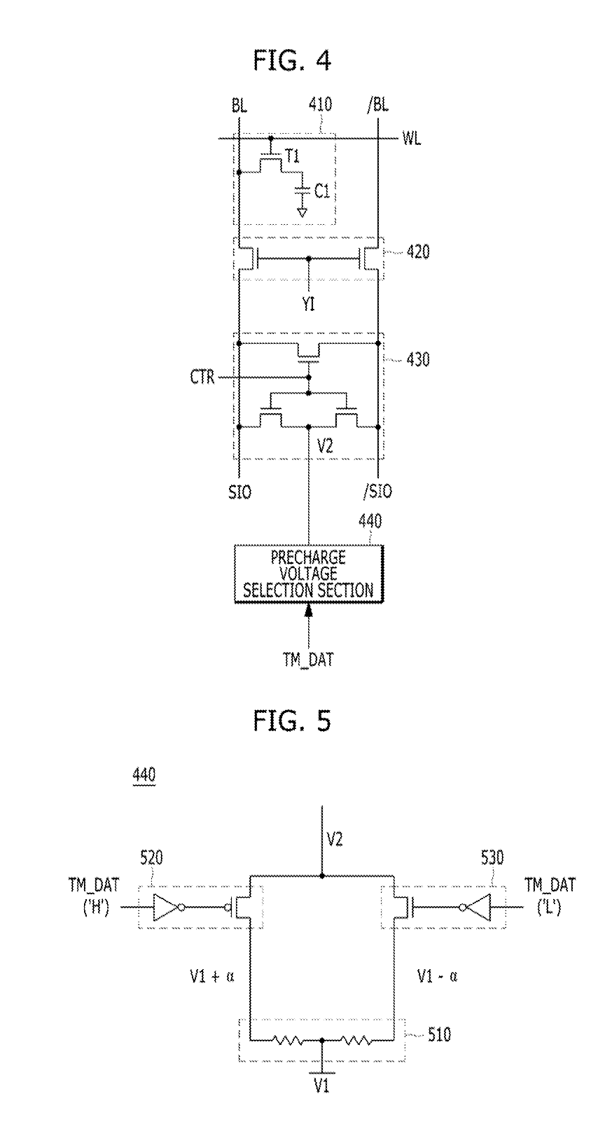

FIG. 4 is a circuit diagram illustrating a semiconductor memory device in accordance with an embodiment of the present invention. The semiconductor memory device shown in FIG. 4 may further include a precharge voltage selection section 440 as well as the elements of the semiconductor memory device described above with reference to FIG. 2. For convenience of the description FIG. 4 shows a memory cell 410, a column selection section 420, and a precharge driving section 430 respectively corresponding to the memory cell 210, the column connection section 240, and the precharge driving unit 252 described above with reference to FIGS. 2 and 3. The memory cell 410, the column selection section 420, and the precharge driving section 430 may be the same as the memory cell 210, the column connection section 240, and the precharge driving unit 252 described above with reference to FIGS. 2 and 3, respectively.

Referring to FIG. 4, the precharge voltage selection section 440 may select and output a voltage corresponding to a test data TM_DAT as the precharge voltage V2. The test data TM_DAT may be stored in the memory cell 410 during the USD test operation. Although the test data having logic ‘LOW’ during the USD test operation is taken as an example, the test data may have logic ‘HIGH’ during the USD test operation, and the precharge voltage selection section 440 may vary the precharge voltage V2 according to the test data.

FIG. 5 is a circuit diagram illustrating the precharge voltage selection section 440 shown in FIG. 4.

Referring to FIG. 5, the precharge voltage selection section 440 may include a voltage generation unit 510, and selection output units 520 and 530.

The voltage generation unit 510 may generate a plurality of test voltages V1+a and V1−a corresponding to the test data TM_DAT. The test data TM_DAT may be stored in the memory cell, and may have logic ‘HIGH’ or logic “LOW”. The plurality of test voltages may include a first test voltage V1+a corresponding to the test data TM_DAT having logic ‘HIGH’ H, and a second test voltage V1−a corresponding to the test data TM_DAT having logic ‘LOW’.

The selection output units 520 and 530 may include a first selection output unit 520 for outputting the first test voltage V1+a as the precharge voltage V2 in response to the test data TM_DAT having logic ‘HIGH’ H, and a second selection output unit 530 for outputting the second test voltage V1−a as the precharge voltage V2 in response to the test data TM_DAT having logic ‘LOW’ L.

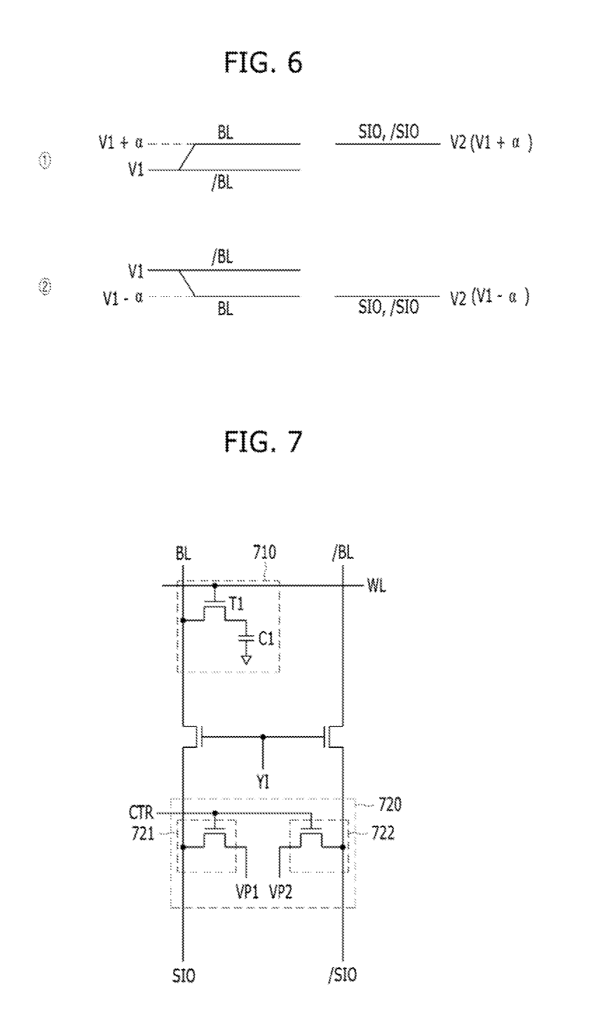

FIG. 6 is a waveform diagram illustrating a USD test operation of the semiconductor memory device shown in FIG. 4.

Referring to FIGS. 4 to 6, “1” is the case of the test data TM_DAT having logic ‘HIGH’ H. As shown in “1”, the positive bit line BL may have a test detection voltage of ‘V1+a’ through the equalization operation and the charge sharing between the cell transistor T1 and the positive bit line BL. The precharge voltage selection section 440 described above with respect to FIGS. 4 and 5 may select and output the first test voltage V1+a as the precharge voltage V2. Eventually, as shown in “1” of FIG. 6, during the failure detection time section “1” of the USD test operation, the positive bit line BL may have the test detection voltage of ‘V1+a’, and the positive and negative segment input/output lines SIO and /SIO may have the first test voltage V1+a. That is, the positive bit line BL and the positive segment input/output line SIO may have the same voltage.

Referring to FIGS. 4 to 6, “2” is the case of the test data TM_DAT having logic ‘LOW’ L. As shown in “2”, the positive bit line BL may have a test detection voltage of ‘V1−a’ through the equalization operation and the charge sharing between the cell transistor T1 and the positive bit line BL. The precharge voltage selection section 440 described above with respect to FIGS. 4 and 5 may select and output the second test voltage V1−a as the precharge voltage V2. Eventually, as shown in “2” of FIG. 6, during the failure detection time section “1” of the USD test operation, the positive bit line BL may have the test detection voltage of ‘V1−a’, and the positive and negative segment input/output lines SIO and /SIO may have the second test voltage V1−a. That is, the positive bit line BL and the positive segment input/output line SIO may have the same voltage.

In accordance with an exemplary embodiment of the present invention, a semiconductor memory device may provide an optimized environment for performing stable USD test operations by minimizing the voltage difference of the positive bit line BL and the positive segment input/output line SIO through control of the precharge voltage V2 according to the test data TM_DAT stored in the memory cell during the USD test operation.

FIG. 7 is a circuit diagram illustrating a semiconductor memory device in accordance with an embodiment of the present invention. The semiconductor memory device shown in FIG. 7 is the same as the semiconductor memory device described above with reference to FIGS. 4 to 6 except for the precharge driving section 430 and a precharge driving section 720. Therefore, the precharge driving section 720 will be described with reference to FIG. 7. For reference, similarly to FIG. 4, FIG. 7 shows part of the semiconductor memory device described above with reference to FIG. 2.

Referring to FIG. 7, the precharge driving section 720 may include a first precharge unit 721 for precharging the positive segment input/output line SIO to a first precharge voltage VP1 in response to a control signal CTR enabled during the failure detection time section, and a second precharge unit 722 for precharging the negative segment input/output bit line /SIO to a second precharge voltage VP2 in response to the control signal CTR. The first precharge voltage VP1 may correspond to the precharge voltage V2 described above with reference to FIGS. 2 to 6, and the second precharge voltage VP2 may correspond to the equalization voltage V1 described above with reference to FIG. 2. As described above, the precharge voltage V2 may correspond to the test detection voltage, which is provided to the positive bit line BL through the equalization operation and the charge sharing between the cell transistor T1 and the positive bit line BL, and the equalization voltage V1 may correspond to the test detection voltage, which is provided to the negative bit line /BL through the equalization operation.

For reference, both of the equalization voltage V1 and the value of stored data in the memory cell 710 may be the test detection voltage of the positive bit line BL, and both of the equalization section (not illustrated) for providing the equalization voltage V1, and the memory cell 710 for providing the value of stored data, may be the voltage supply part. Also, the equalization voltage V1 may be the test detection voltage of the negative bit line /BL, and the equalization section for providing the equalization voltage V1 may be the voltage supply part.

To sum up, during the failure detection time section, the positive bit line BL and the positive segment input/output line SIO may have the same voltage, and the negative bit line /BL and the negative segment input/output bit line /SIO may have the same voltage.

In accordance with an exemplary embodiment of the present invention, a semiconductor memory device may provide an optimized environment for performing stable USD test operations by minimizing the voltage difference of the positive bit line BL and the positive segment input/output line SIO, as well as the voltage difference between the negative bit line /BL and the negative segment input/output bit line /SIO during the failure detection time section.

As described above, In accordance with an exemplary embodiment of the present invention, a semiconductor memory device may provide an optimal environment for a stable USD test operation by controlling peripheral circuits during the USD test operation. Therefore, the semiconductor memory device may elevate the reliability of the result of the USD test operation.

By performing the USD test operation in an optimal environment, a reliable test result of the USD test may be obtained.

While the present invention has been described with respect to specific embodiments, it will be apparent to those skilled in the art that various changes and modifications may be made without departing from the spirit and scope of the invention as defined in the following claims.

For example, the position and type of logic gates and transistors described above as examples may be changed according to the polarity of the input signals.

What is claimed is:

1. A semiconductor memory device comprising:
a voltage supply part suitable for providing predetermined test detection voltages to a pair of bit lines, respectively, during a test operation for detecting a failure between a word line and the pair of bit lines;
a column connection section suitable for electrically coupling the pair of bit lines and a pair of segment lines to each other, respectively, in response to a column selection signal; and
a precharge section suitable for precharging the pair of segment lines to a precharge voltage corresponding to one of the test detection voltages during a failure detection time section while performing the test operation.

2. The semiconductor memory device of claim 1, further comprising a sense amplification section suitable for detecting and amplifying a voltage difference between the pair of bit lines after the failure detection time section during the test operation.

3. The semiconductor memory device of claim 1, wherein the precharge section comprises:
a precharge driving unit suitable for driving the pair of segment lines to the precharge voltage; and
a precharge control unit suitable for controlling the precharge driving unit during the test operation.

4. The semiconductor memory device of claim 1, further comprising a precharge voltage selection section suitable for selecting a test voltage corresponding to a test data stored during the test operation in a memory cell of the semiconductor memory device as the precharge voltage.

5. The semiconductor memory device of claim 4, wherein the precharge voltage selection section comprises:
a voltage generation unit suitable for generating a plurality of test voltages respectively corresponding to a plurality of possible test data; and
a selection output unit suitable for selecting one among the plurality of test voltages corresponding to the test data stored during the test operation in the memory cell as the precharge voltage.

6. The semiconductor memory device of claim 1, wherein the test detection voltages include voltages provided to the pair of bit lines through an equalization operation and a charge sharing between a memory cell of the semiconductor memory device and one of the pair of bit lines.

7. The semiconductor memory device of claim 1, wherein the voltage supply part comprises:
an equalization section suitable for equalizing the pair of bit lines to an equalization voltage; and
a memory cell electrically coupled to the word line and one of the pair of bit lines.

8. The semiconductor memory device of claim 7, wherein the precharge voltage corresponds to the equalization voltage.

9. The semiconductor memory device of claim 7, wherein the precharge section comprises:
a precharge driving unit suitable for driving the pair of segment lines to the equalization voltage; and
a precharge control unit suitable for controlling the precharge driving unit during the test operation.

10. The semiconductor memory device of claim 1, further comprising an input/output connection section suitable for electrically coupling the pair of segment lines and a pair of local input/output lines to each other, respectively, in response to an input/output selection signal.

11. The semiconductor memory device of claim 10, wherein the input/output connection section is activated after the failure detection time section.

12. A semiconductor memory device comprising:
a pair of bit lines including first and second bit lines;
a voltage supply part suitable for providing predetermined test detection voltages to each of the first and second bit lines, respectively, during a test operation for detecting a failure between a word line and the pair of bit lines;
a column connection section suitable for electrically coupling the first and second bit lines and first and second segment lines to each other, respectively, in response to a column selection signal; and
a precharge section suitable for precharging the first and second segment lines to first and second precharge voltages corresponding to the test detection voltages during a failure detection time section while performing the test operation.

13. The semiconductor memory device of claim 12, wherein the precharge section comprises:
a first precharge unit suitable for precharging the first segment line to a first precharge voltage; and
a second precharge unit suitable for precharging the second segment bit line to a second precharge voltage.

14. The semiconductor memory device of claim 13, wherein the voltage supply part comprises:
an equalization section suitable for equalizing the pair of bit lines to an equalization voltage; and
a memory cell electrically coupled to the word line and the first bit line.

15. The semiconductor memory device of claim 14, wherein each of the first precharge voltage and the test detection voltage provided to the first bit line corresponds to the equalization voltage and a charge-shared voltage between the memory cell and the first bit line.

16. The semiconductor memory device of claim 14, wherein the first precharge unit comprises:
a precharge driving unit suitable for driving the first segment line to the first precharge voltage; and
a precharge control unit suitable for controlling the precharge driving unit during the test operation.

17. The semiconductor memory device of claim 16, further comprising a precharge voltage selection section suitable for selecting a test voltage corresponding to a test data stored during the test operation in the memory cell as the first precharge voltage.

18. The semiconductor memory device of claim 14, wherein each of the second precharge voltage and the test detection voltage provided to the second bit line corresponds to the equalization voltage.

19. The semiconductor memory device of claim 12, further comprising an input/output connection section suitable for electrically coupling the pair of segment lines and a pair of local input/output lines to each other, respectively, in response to an input/output selection signal.

20. The semiconductor memory device of claim 19, wherein the input/output connection section is activated after the failure detection time section.
